(19) United States
(12) Patent Application Publication
(10) Pub. No.: US 2024/0177945 A1
(43) Pub. Date: May 30, 2024

(54) ELECTRONIC-COMPONENT-PROTECTION STRUCTURE AND SWITCH DEVICE

(71) Applicants: TOYO DENSO KABUSHIKI KAISHA, Tokyo (JP); HONDA MOTOR CO., LTD., Tokyo (JP)

(72) Inventors: Toshiyuki SHINOZAWA, Tsurugashima-shi (JP); Hideaki ITOU, Tsurugashima-shi (JP); Yoshiya SUZUKI, Tsurugashima-shi (JP); Kenta TANIGAWA, Tokyo (JP); Hiroyuki SHIBASAKI, Tokyo (JP)

(21) Appl. No.: 18/517,173

(22) Filed: Nov. 22, 2023

(30) Foreign Application Priority Data
Nov. 28, 2022 (JP) 2022-189592

(51) Int. Cl. H01H 1/58; H01H 19/04; H01H 19/08; H01H 25/06

(52) U.S. Cl. CPC H01H 1/5805; H01H 19/04; H01H 19/08; H01H 25/06

(57) ABSTRACT

An electronic-component-protection structure which can protect, with a simple configuration, an electronic component from static electricity that may be charged in a case member. A ground member having conductivity is integrally formed with a circuit board or electrically connected to the circuit board, wherein the circuit board has an electronic component mounted thereon. A housing includes a base member and a case member and accommodates the circuit board and a ground member. A sealing member, which is a conductive elastic member disposed between the base member and the case member, is at least partly exposed to the outside of the housing.

### BACKGROUND OF THE INVENTION

### Field of the Invention

The present invention relates to an electronic-component-protection structure and a switch device.

### Description of the Related Art

Conventionally known electronic apparatuses are equipped with circuit boards on which electronic components, such as integrated circuits (ICs), are mounted. Some of such electronic apparatuses have protection structures that protect the electronic components from static electricity.

For example, Japanese Patent Application Laid-Open No. 2015-15202 discloses a device that is highly resistant to static electricity. In this device, the entire perimeter of a capacitance sensor is surrounded by a conductive material that is provided on a side wall formed by two cases, and an insulating member is provided on the entire perimeters of engagement sections of the two cases, which implements the high static electricity resistant.

Japanese Utility Model Application Laid-Open No. 61-19938 discloses a device configured to suppress corona discharging. In this device, conductive packing for gas sealing is provided between two insulating containers, and is connected to the ground potential, which suppresses corona discharging.

However, the device disclosed in Japanese Patent Application Laid-Open No. 2015-15202 requires an insulating member. The device described in Japanese Utility Model Application Laid-Open No. 61-19938 requires to connect the packing to the ground terminal provided outside. Therefore, such conventional techniques have room for improvement, in terms of protecting electronic components from static electricity without involving complicated configurations.

### SUMMARY OF THE INVENTION

The present invention provides an electronic-component-protection structure which enables, by a simple configuration, the protection of an electronic component from static electricity that may be charged in a case member, as well as a switch device equipped with the electronic-component-protection structure.

Accordingly, the present invention provides an electronic-component-protection structure comprising a circuit board on which an electronic component is mounted, a ground member having conductivity, which is integrally formed with the circuit board or that is electrically connected to the circuit board, a housing including a base member and a case member, which accommodates the circuit board and the ground member, and a conductive elastic member disposed between the base member and the case member, wherein at least a portion of the conductive elastic member is exposed to outside of the housing.

According to the present invention, an electronic component can be protected with a simple configuration from static electricity that may be charged in a case member.

Further features of the present invention will become apparent from the following description of exemplary embodiments with reference to the attached drawings.

### BRIEF DESCRIPTION OF THE DRAWINGS

FIG. 1 is a perspective view of a switch device equipped with an electronic-component-protection structure according to an embodiment of the present invention.

FIG. 2 is an exploded perspective view of the switch device in FIG. 1.

FIG. 3 is a view as viewed from the direction of arrow A in FIG. 2.

FIG. 4 is a perspective view of the circuit board and the ground member in FIG. 2.

FIG. 5 is a perspective view of the ground member in FIG. 4.

FIG. 6 is a perspective view of a positional relationship between the circuit board, the case member, and the ground member in the switch device in FIG. 1.

FIG. 7 is a view as viewed from the direction of arrow B in FIG. 6.

FIG. 8 is a view of the base member as viewed from the +Z side.

FIG. 9 is a cross-sectional view taken along line A-A in FIG. 8.

FIGS. 10A and 10B are cross-sectional views taken along line A-A in FIG. 8, wherein FIG. 10A illustrates a first variation of the switch device, and FIG. 10B illustrates a second variation of the switch device.

### DESCRIPTION OF THE EMBODIMENTS

Each embodiment of the present invention will be described below in detail with reference to the drawings. However, configurations described in the following embodiments are merely examples, and thus the scope of the present invention is not limited by the configurations described in the embodiments.

Hereinafter, an X axis, Y axis, and Z axis that are orthogonal to one another are imagined (defined) in each figure. The X-axis direction corresponds to a direction parallel to a width of a switch device. The Y-axis direction corresponds to a direction parallel to a depth of the switch device. The Z-axis direction corresponds to a direction parallel to a height of the switch device. In each figure, the side (direction) to which the arrow of each axis points is referred to as the “positive side” (“+” side), whereas the opposite side (direction) thereto is referred to as the “negative side” (“−” side). It should be noted that the positive side (+Z side) in the Z-axis direction is also referred to as the “upper side”, whereas the negative side (−Z side) in the Z-axis direction is also referred to as the “lower side”.

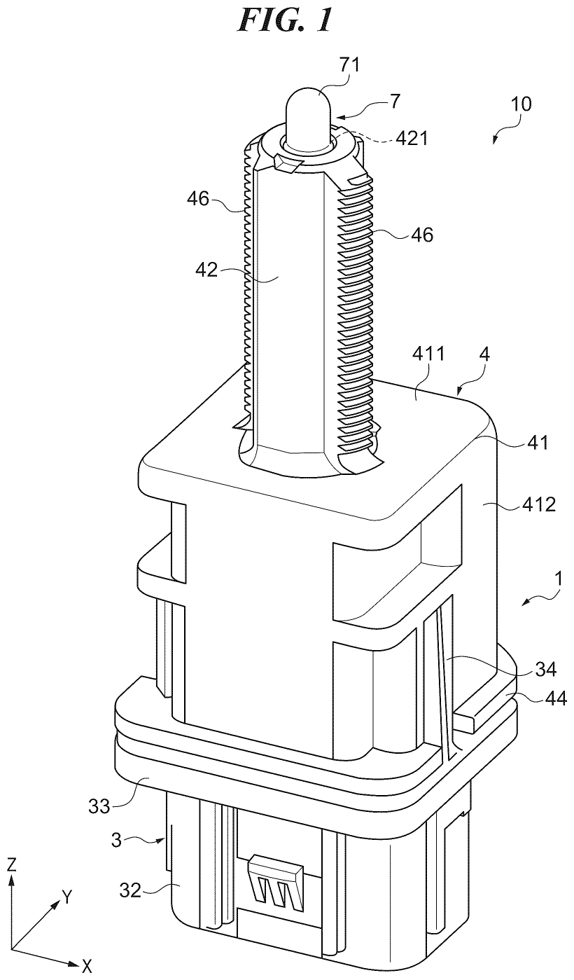

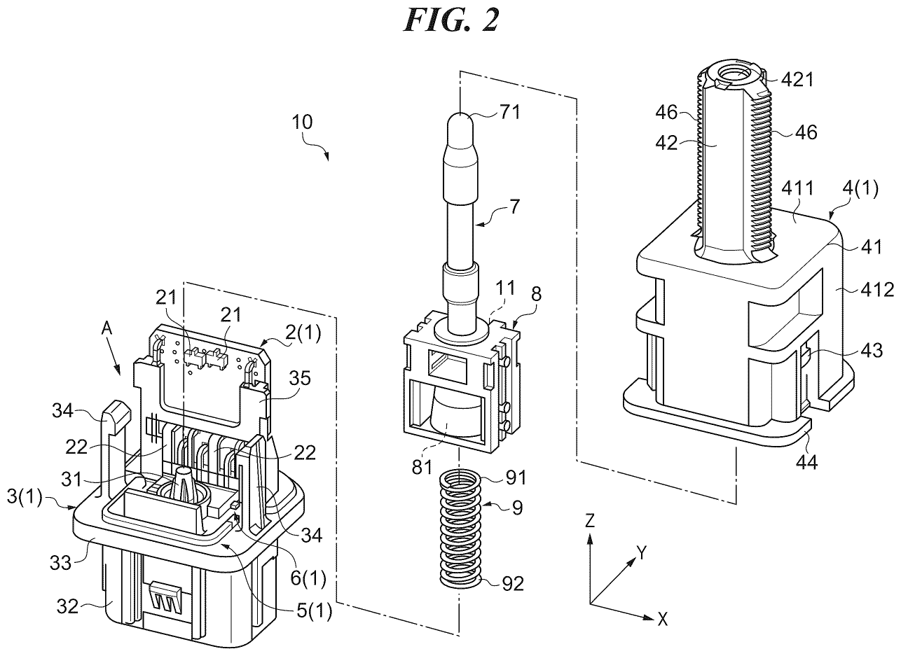

FIG. 1 is a perspective view of a switch device 10 equipped with an electronic-component-protection structure 1 according to an embodiment of the present invention. FIG. 2 is an exploded perspective view of the switch device 10 in FIG. 1.

The switch device 10 with the electronic-component-protection structure 1 illustrated in FIG. 1 is, when being used, installed near the base of a pedal (not illustrated), such as a brake or a clutch in an automobile, for example. The switch device 10 is a device that, when a pedal is depressed, detects the depression and provides an output of a result of the detection electrically. The switch device 10 may electrically output the depression amount. It should be noted that the switch device 10 is not limited to a device to be mounted on an automobile.

As illustrated in FIG. 2, the electronic-component-protection structure 1 includes a circuit board 2, a base member 3, a case member 4, a sealing member 5, and a ground member 6. The electronic-component-protection structure 1 corresponds to a structure that protects electronic components 21 on the circuit board 2. The base member 3 and the case member 4 constitute a housing, which accommodates the circuit board 2 and the ground member 6.

The switch device 10 includes the electronic-component-protection structure 1, and also a rod 7, a magnet holder 8, a coil spring 9, and a magnet 11. Prior to the description of the electronic-component-protection structure 1, the rod 7, the magnet holder 8, the coil spring 9, and the magnet 11 will be described below.

The rod 7 (operation unit) is a cylindrical member extending in the Z-axis direction and supported in such a way that the rod 7 can reciprocate in the Z-axis direction. The rod 7 has an upper end (tip) that protrudes from the case member 4 via an upper opening 421 (see FIG. 1). The rod 7 has a hemispherically rounded upper surface 71 that abuts to a predetermined member out of members constituting the pedal. When the driver of the automobile steps in and operates the pedal, the rod 7 moves upward by means of a biasing force of the coil spring 9. When the driver releases the stepping force from the pedal, the rod 7 pressed downward against the biasing force of the coil spring 9. The magnet holder 8 is disposed below the rod 7. The magnet holder 8 can reciprocate in the Z-axis direction together with the rod 7. The magnet holder 8, which has a block shape, retains the magnet 11 on its positive side in the Y-axis direction.

The coil spring 9 is disposed below the magnet holder 8. The coil spring 9 is kept compressed between the magnet holder 8 and the base member 3. In this way, the rod 7 can be biased upward. The coil spring 9 has an upper end 91 inserted into a recess 81 of the magnet holder 8; the base member 3 has a projection 31 inserted into a lower end 92 of the coil spring 9. In this way, the position and posture of the coil spring 9 are regulated, so that the coil spring 9 can be stably expanded and compressed in the Z-axis direction. It should be noted that the relationship between the pedal depression (pedaling) and the movement of the rod 7 may be opposite to that in the present embodiment.

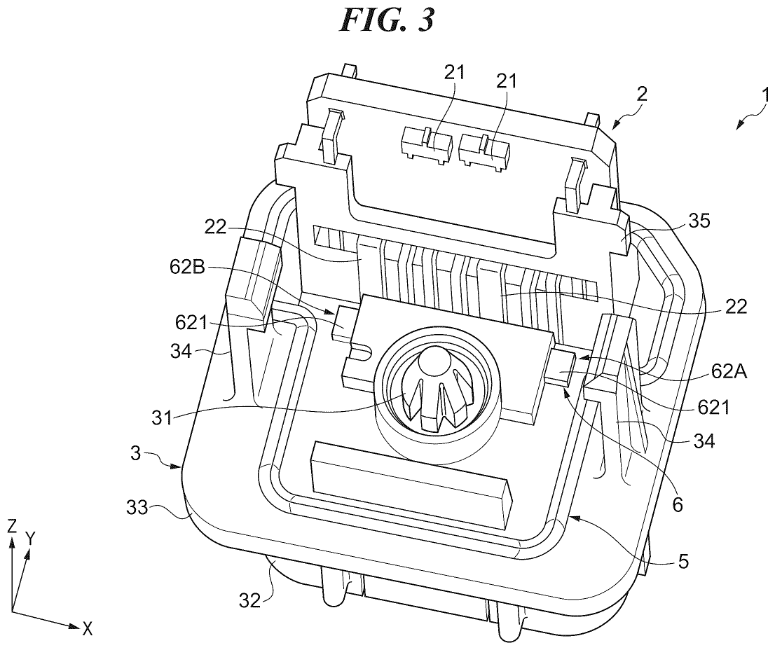

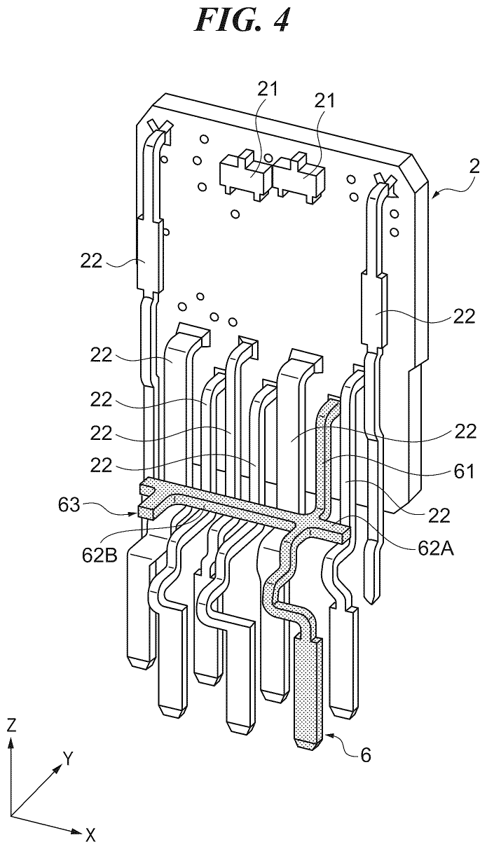

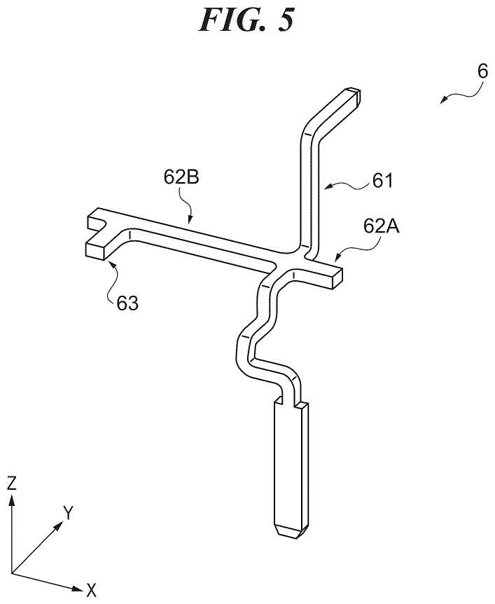

FIG. 3 is a view as viewed from the direction of arrow A in FIG. 2. FIG. 4 is a perspective view of the circuit board 2 and the ground member 6 in FIG. 2. FIG. 5 is a perspective view of the ground member 6 in FIG. 4.

As illustrated in FIG. 3, the circuit board 2 are supported by the base member 3, with the thickness direction of the circuit board 2 being parallel to the Y-axis direction. One or more electronic components 21 are mounted on at least one surface of the circuit board 2.

Examples of the electronic component 21 include an integrated circuit (IC) and a Hall element. A Hall element is a magnetic sensor utilizing the Hall effect. The rod 7 reciprocates in accordance with the pedaling, so that the positional relationship between the Hall element and the magnet 11 held by the magnet holder 8 changes. With this change in the positional relationship, the voltage generated in the Hall element is detected as the pedaling amount of the pedal and is then output. That is, the electronic components 21 detect the movement of the rod 7, which is the operation unit provided so as to be able to reciprocate in at least one direction, and then convert the detected movement (detection result) into an electrical output.

As illustrated in FIG. 4, a plurality of terminals 22 are connected to the circuit board 2. Each terminal 22 is electrically connected to a predetermined electronic component 21 via a circuit pattern (not illustrated). Each terminal 22 extends downward as a whole.

As illustrated in FIGS. 2 and 3, the base member 3 includes a hollow body 32, a pair of claws 34 protruding from the hollow body 32, and a support section 35 that protrudes from the hollow body 32 and that supports the circuit board 2. The hollow body 32, the pair of claws 34 and support section 35 integrally form the base member 3. The base member 3 is made of resin material, such as polybutylene terephthalate (PBT), for example. As a result, the base member 3 can be easily molded with a molding die during the manufacturing of the base member 3. The terminals 22 extending from the circuit board 2 are exposed inside the hollow body 32, wherein the hollow body 32 functions as a connector housing that supports and fixes each terminal 22. An external connector (not illustrated) can be inserted into the hollow body 32. As a result, the terminal of the inserted external connector can be electrically connected to each terminal 22.

The hollow body 32 has an outer circumference from which a flange 33 is formed so as to protrude. The pair of claws 34 are formed so as to protrude upward from the flange 33. These claws 34 are arranged apart from each other in the X-axis direction and can engage with the case member 4 from the outside. In this way, the case member 4 can be fixed to the base member 3. The projection 31 to be inserted into the lower end 92 of the coil spring 9 is disposed between the claws 34. The support section 35 is formed so as to protrude upward from the flange 33. The support section 35 clamps the circuit board 2 in the X-axis direction. As a result, the circuit board 2 is supported by the base member 3.

As illustrated in FIGS. 1 and 2, the case member 4 is a member that is disposed above the base member 3 and covers the circuit board 2. The case member 4 includes a portion having a box-shape (box-shaped section) 41, and a cylindrical section 42 cylindrically protruding from the box-shaped section 41. The box-shaped section 41 and the cylindrical section 42 integrally form the case member 4. Similar to the base member 3, the case member 4 is made of resin material, such as polybutylene terephthalate (PBT), for example.

Thus, the case member 4 can be easily molded with a molding die during the manufacturing of the case member 4.

The box-shaped section 41 includes a top plate 411, and a side wall 412 formed downward from the outer edge of the top plate 411. The side wall 412 is provided with engagement sections 43 which engage with the respective claws 34 of the base member 3. When the claws 34 engages with the engagement sections 43, the case member 4 is fixed to the base member 3. The side wall 412 has outer circumference from which a flange 44 is formed so as to protrude.

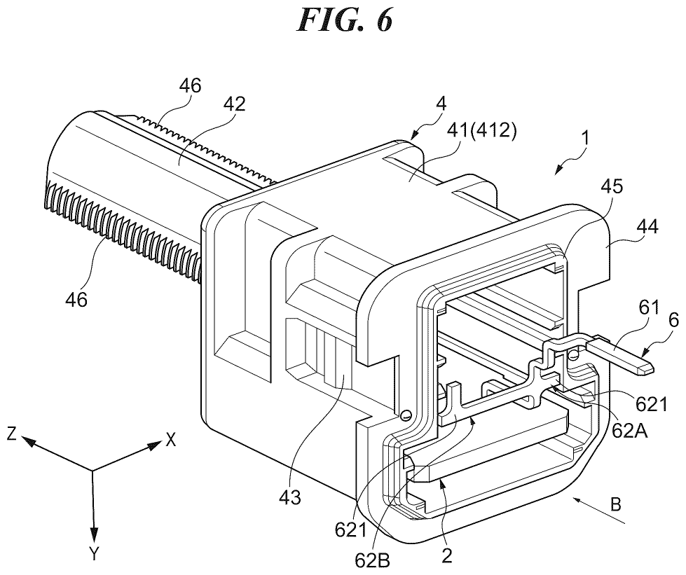

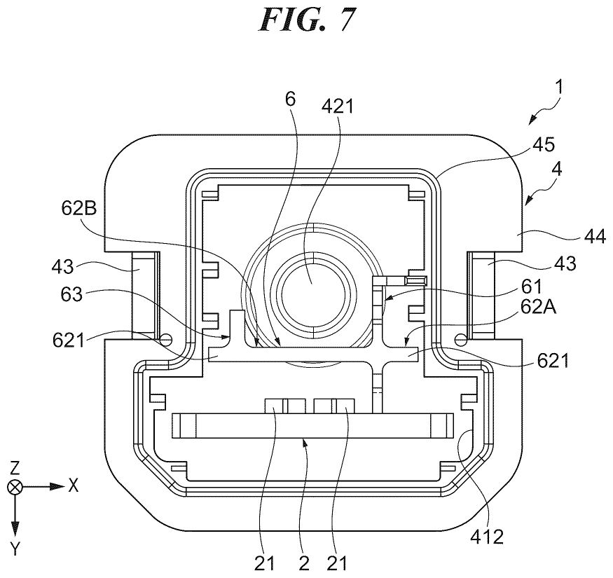

FIG. 6 is a perspective view of the positional relationship between the circuit board 2, the case member 4, and the ground member 6 in the switch device 10 in FIG. 1. FIG. 7 is a view as viewed from the direction of arrow B in FIG. 6.

As illustrated in FIGS. 6 and 7, the flange 44 has a regulating section 45 that protrudes downward from the flange 44. The regulating section 45 is formed into a ring shape (closed shape) along the circumference of the side wall 412. The regulating section 45 regulates a compression limit of the sealing member 5 when the sealing member 5 is compressed between the flange 33 of the base member 3 and the flange 44 of the case member 4. As illustrated in FIG. 1, the cylindrical section 42 having the upper opening 421 protrudes upward from the top plate 411 of the box-shaped section 41. The rod 7 is slidably supported inside the cylindrical section 42. As a result, the rod 7 can stably reciprocate in the Z-axis direction while being guided by the cylindrical section 42. It should be noted that a male screw 46 to be screwed with an attachment (not illustrated) for the switch device 10 is formed on an outer circumference of the cylindrical section 42; however, the male screw 46 is optional.

As illustrated in FIG. 2, the sealing member 5 is provided between the base member 3 and the case member 4. The sealing member 5 has a ring shape that is similar to that of the regulating section 45 of the case member 4. As described above, the sealing member 5 is compressed between the flange 33 of the base member 3 and the flange 44 of the case member 4. The sealing member 5 is thus able to seal the gap between the base member 3 and the case member 4 by bringing its entire perimeter into close contact with both the flange 33 and the flange 44. That is, the sealing member 5 is elastically sandwiched between the base member 3 and the case member 4. As a result, the waterproofness between the base member 3 and the case member 4 is ensured, thereby preventing water and other substances from entering the case member 4, which makes it possible to protect the circuit board 2. The regulating section 45 (see FIG. 6) of the case member 4 is positioned inside the sealing member 5 having a ring shape. The regulating section 45 of the case member 4 regulates the compression limit of the sealing member 5. The sealing member 5 is thus compressed without excess or deficiency.

The sealing member 5 is a conductive elastic member. The sealing member 5 is made of a material having conductivity and elasticity. For example, the sealing member 5 is made of the material obtained by adding a conductive substance, such as carbon, a metal material, or the like, to an elastic material, such as nitrile rubber (NBR), silicone rubber, or the like. However, the material of the conductive elastic member applied to the sealing member 5 is not limited to this example. Further, the electric resistance value of the sealing member 5 is set to be less than any of the electric resistance values of the base member 3 and the case member 4; however, which is not essential.

As illustrated in FIG. 4, the ground member 6 is connected to the circuit board 2. The ground member 6 is a ground (GND) line of the circuit board 2 and is made of a conductive material such as a copper alloy, for example. As illustrated in FIG. 5, the ground member 6 is a linear (has a long and narrow shape), and includes: a line section 61 forming a main body of the ground member 6; and a protrusion 62A and a protrusion 62B, each of which protrudes from the line section 61. The line section 61 is curved at a plurality of midway points in a longitudinal direction thereof. The protrusion 62A branches off from the line section 61 at one midway point in a longitudinal direction of the line section 61 and extends linearly toward the positive side in the X-axis direction. The protrusion 62B also branches off from the line section 61 at one midway point (which is the same point as the branching point of the protrusion 62A, in this embodiment) in the longitudinal direction of the line section 61 and extends linearly toward the negative side in the X-axis direction. In this embodiment, the protrusion 62B is greater in total length than the protrusion 62A. In addition, a protrusion 63 which branches off from the protrusion 62B at a midway point in a longitudinal direction of the protrusion 62B and protrudes to the negative side in the Y-axis direction is provided; however, the protrusion 63 is optional.

As illustrated in FIG. 3, at least ends (portions) of the protrusion 62A and the protrusion 62B are exposed inside the case member 4, thereby forming respective exposed sections 621. As illustrated in FIGS. 6 and 7, each exposed section 621 protrudes toward the side wall 412 of the case member 4. It should be noted that the terminals 22 are omitted in FIGS. 6 and 7. In this embodiment, the exposed section 621 of the protrusion 62A protrudes toward the side wall 412 of the case member 4, toward the positive side in the X-axis direction, whereas the exposed section 621 of the protrusion 62B protrudes toward the side wall 412 of the case member 4, toward the negative side in the X-axis direction.

Next, protection of the electronic components 21 by the sealing member 5 will be described below.

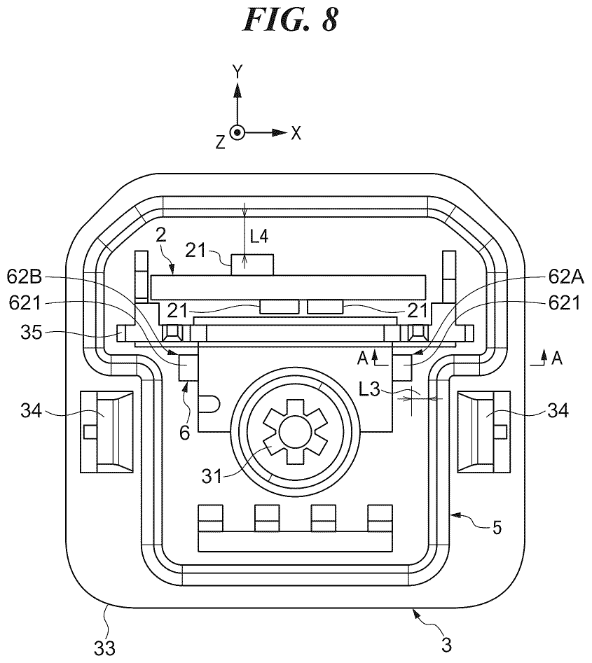

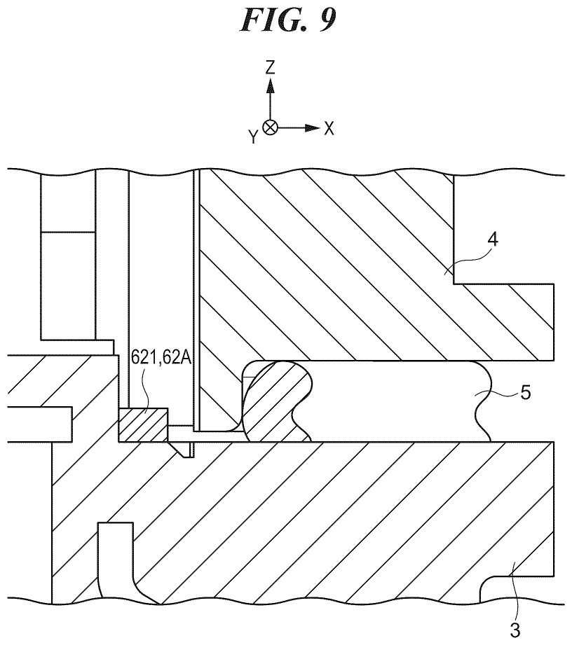

FIG. 8 is a view of the base member 3 as viewed from the +Z side. FIG. 9 is a cross-sectional view taken along line A-A of FIG. 8. It should be noted that illustration of the terminals 22 are omitted in FIG. 8.

At least a portion of the sealing member 5 disposed between the base member 3 and the case member 4 is exposed to the outside of the housing, which is formed by the base member 3 and the case member 4. In this embodiment, the sealing member 5 is disposed so as to surround the entire perimeters of the circuit board 2 and the ground member 6 as viewed from the Z-axis direction. The entire perimeter of the sealing member 5 is exposed to the outside through the gap between the base member 3 and the case member 4, that is, exposed to the outside between the opposing surfaces of the base member 3 and the case member 4.

As illustrated in FIG. 8, a shortest distance L3 between the sealing member 5 and the ground member 6, is set to be shorter than a shortest distance L4 between sealing member 5 and the electronic component 21. In considering the distance between the sealing member 5 and the ground member 6, the ground member 6 may be a conductive member (including a ground pattern or a lightning rod formed on the circuit board 2) that is integrally formed with the circuit board 2 or that is electrically connected to the circuit board 2. In the configuration example of FIG. 8, the closest portion of the ground member 6 to the sealing member 5 is the protrusion 62A (or the protrusion 62B).

In considering the distances between the sealing member 5 and the electronic components 21, in a case where a plurality of electronic components 21 are present, the electronic component 21 positioned closest to the sealing member 5 is focused on.

According to this embodiment, the housing formed by the base member 3 and the case member 4 accommodates both the circuit board 2 on which the electronic components 21, and the ground member 6 are mounted. The sealing member 5, which is the conductive elastic member disposed between the base member 3 and the case member 4, is at least partly exposed to the outside of the housing. With this configuration, static electricity from outside is more likely to be led to the sealing member 5 and thus static electricity is not likely to be transmitted to the electronic components 21. In this case, no insulating member is required to protect the electronic components 21 from static electricity. Further, it is unnecessary to connect the sealing member 5 to the ground terminal provided outside. Therefore, the configuration in this embodiment can be simpler than conventional ones.

It is thus possible to protect, with a simple configuration, the electronic components 21 from static electricity charged on the case member 4. In particular, the sealing member 5 is disposed so as to surround the entire perimeters of the circuit board 2 and the ground member 6, thereby enhancing the effect of protecting the electronic components 21.

The electric resistance value of the sealing member 5 is set to be less than that of any of the base member 3 and the case member 4, which can help to lead static electricity from outside more easily to the sealing member 5, and to enhance the effect of protecting the electronic components 21.

The shortest distance L3 between the sealing member 5 and the ground member 6 is set to be shorter than the shortest distance L4 between the sealing member 5 and the electronic component 21. As a result, static electricity from outside is lead to the ground member 6 through the sealing member 5 more easily, thereby enhancing an effect of suppressing the static electricity from being transmitted to the electronic components 21, and enhancing the protection of the electronic components 21.

The sealing member 5 is elastically sandwiched between the base member 3 and the case member 4, which makes the sealing member 5 possible to also have a waterproof function by simple configuration. In addition, the sealing member 5 is exposed to the outside through between the opposing surfaces of the base member 3 and the case member 4, which makes it possible to lead static electricity from outside easily, while ensuring the waterproofness.

Only in terms of protection of the electronic components 21 from static electricity, it is not essential that the sealing member 5 is disposed so as to surround the entire perimeters of the circuit board 2 and the ground member 6 as viewed from the Z-axis direction, and the sealing member 5 may be have a partially interrupted annular shape.

If only the protection of the electronic components 21 from static electricity is focused on and sufficient waterproofness is unnecessary, the sealing member 5 does not necessarily have to be in close contact with the entire perimeters of the base member 3 and the case member 4. In this case, the sealing member 5 may be referred to as the “conductive elastic member” rather than the “sealing member”.

The circuit board 2 does not necessarily have to be supported by the base member 3; alternatively, the circuit board 2 may be supported by the case member 4 or another member.

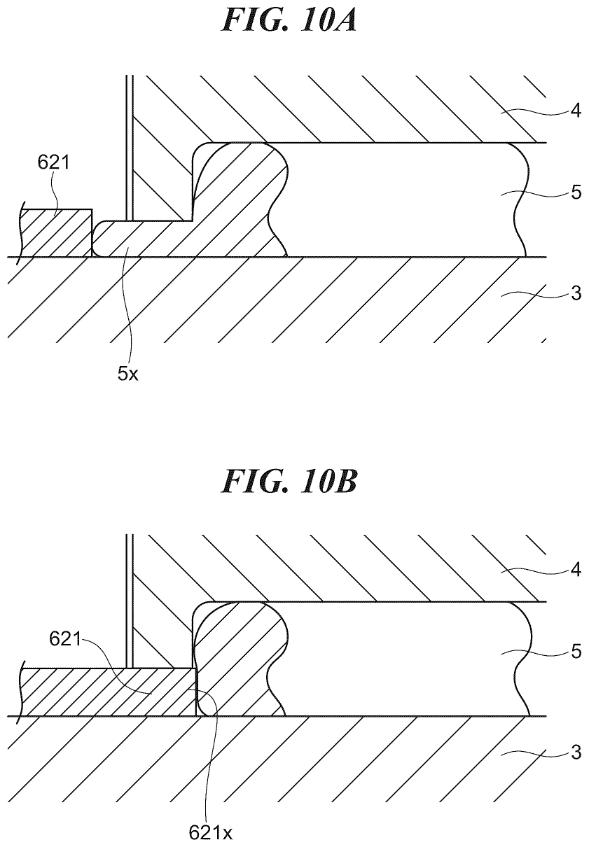

In the present embodiment mentioned above, the sealing member 5 and the ground member 6 are spaced at least by the shortest distance L3. However, as illustrated in FIGS. 10A and 10B, the shape of the sealing member 5 and/or the ground member 6 may be modified, and the sealing member 5 and the ground member 6 may be in contact with each other.

FIG. 10A illustrates a first variation of the switch device 10, and FIG. 10B illustrates a second variation of the switch device 10. FIGS. 10A and 10B are cross-sectional views taken along a line corresponding to line A-A (FIG. 8) in the switch device 10. The reference characters illustrated in FIGS. 10A and 10B correspond to those illustrated in FIG. 8.

As shown in the first variation (FIG. 10A), a part (portion) 5x of a sealing member 5 may extend into (toward) the inside of a housing through the gap between a base member 3 and a case member 4, and may be in contact with a portion of an exposed section 621 of a ground member 6.

Alternatively, as shown in the second variation (FIG. 10B), a part 621x of an exposed section 621 of a ground member 6 may extend to (toward) the outside of a housing through a gap between a base member 3 and a case member 4, and may be in contact with a sealing member 5.

The above variations contribute to more preferential electrical discharge from the case member 4 to the exposed section 621. As a result, it is possible to lead static electricity from outside more easily, from the sealing member 5 to the ground member 6, thereby enhancing the protection of the electronic components 21. It should be noted that, a structure can be adopted, in which a portion of the sealing member 5 and a portion of the exposed section 621 may extend toward each other and are in contact with each other in the gap between the base member 3 and the case member 4.

The preferred embodiments of the present invention have been described above; however, the present invention is not limited to such embodiments, and various modifications and variations can be made within the scope or spirit of the present technology. In this embodiment, as an example, the electronic-component-protection structure 1 is applied to the switch device 10; however, the application aspect is not limited to the switch device 10 and is also applicable to other various electronic apparatuses.

This application claims the benefit of Japanese Patent Application No. 2022-189592, filed Nov. 28, 2022, which is hereby incorporated by reference wherein in its entirety.

What is claimed is:

1. An electronic-component-protection structure comprising:
a circuit board on which an electronic component is mounted;
a ground member having conductivity, which is integrally formed with the circuit board or that is electrically connected to the circuit board;
a housing including a base member and a case member, which accommodates the circuit board and the ground member; and
a conductive elastic member disposed between the base member and the case member,
wherein at least a portion of the conductive elastic member is exposed to outside of the housing.

2. The electronic-component-protection structure according to claim 1, wherein an electric resistance value of the conductive elastic member is less than an electric resistance value of any of the base member and the case member.

3. The electronic-component-protection structure according to claim 1, wherein a shortest distance between the conductive elastic member and the ground member is shorter than a shortest distance between the conductive elastic member and the electronic component.

4. The electronic-component-protection structure according to claim 1, wherein the conductive elastic member is disposed so as to surround entire perimeters of the circuit board and the ground member.

5. The electronic-component-protection structure according to claim 4, wherein the conductive elastic member is elastically sandwiched between the base member and the case member.

6. The electronic-component-protection structure according to claim 5, wherein the conductive elastic member is exposed to outside through between opposing surfaces of the base member and the case member.

7. The electronic-component-protection structure according to claim 1, wherein a portion of the conductive elastic member is in contact with a portion of the ground member.

8. The electronic-component-protection structure according to claim 7, wherein the portion of the conductive elastic member extends into an inside of the housing and is in contact with the portion of the ground member.

9. A switch device comprising:
an operation unit provided so as to be able to reciprocate in at least one direction; and
an electronic-component-protection structure comprising:
a circuit board on which an electronic component is mounted, the electronic component being configured to detect movement of the operation unit and to output a detection result;
a ground member having conductivity, which is integrally formed with the circuit board or that is electrically connected to the circuit board;
a housing including a base member and a case member, which accommodates the circuit board and the ground member; and
a conductive elastic member disposed between the base member and the case member,
wherein at least a portion of the conductive elastic member is exposed to outside of the housing.

10. The switch device according to claim 9, wherein an electric resistance value of the conductive elastic member is less than an electric resistance value of any of the base member and the case member.

11. The switch device according to claim 9, wherein a shortest distance between the conductive elastic member and the ground member is shorter than a shortest distance between the conductive elastic member and the electronic component.

12. The switch device according to claim 9, wherein the conductive elastic member is disposed so as to surround entire perimeters of the circuit board and the ground member.

13. The switch device according to claim 12, wherein the conductive elastic member is elastically sandwiched between the base member and the case member.

14. The switch device according to claim 13, wherein the conductive elastic member is exposed to outside through between opposing surfaces of the base member and the case member.

15. The switch device according to claim 9, wherein a portion of the conductive elastic member is in contact with a portion of the ground member.

16. The switch device according to claim 15, wherein the portion of the conductive elastic member extends into an inside of the housing and is in contact with the portion of the ground member.
